(19) United States
(12) Patent Application Publication
(10) Pub. No.: US 2026/0262420 A1
(43) Pub. Date: Sep. 3, 2026

(54) WINDOW, METHOD OF MANUFACTURING THE WINDOW, AND ELECTRONIC DEVICE INCLUDING THE WINDOW

(71) Applicant: Samsung Display Co., LTD., Yongin-si (KR)

(72) Inventor: Byung-Chul OH, Yongin-si (KR)

(21) Appl. No.: 19/392,619

(22) Filed: Nov. 18, 2025

(30) Foreign Application Priority Data
Feb. 28, 2025 (KR) 10-2025-0026352
May 22, 2025 (KR) 10-2025-0066805

(51) Int. Cl. H10K 59/80; B24B 29/02; B28D 1/30

(52) U.S. Cl. CPC H10K 59/873; B24B 29/02; B28D 1/30

(57) ABSTRACT

A window is provided including a transmission area, a bezel area surrounding the transmission area, a base substrate including an upper surface, a lower surface opposite to the upper surface, and a side surface connecting the upper surface and the lower surface, and a bezel pattern disposed under the base substrate and overlapping the bezel area. The side surface includes a first side surface parallel to a thickness direction of the base substrate, a second side surface extending from the first side surface and connected to the lower surface, and a third side surface extending from the first side surface and connected to the upper surface. The second side surface includes a second-first side surface adjacent to the first side surface and a second-second side surface adjacent to the lower surface. An obtuse angle between the lower surface and the second-second side surface is greater than about 135 degrees.

### CROSS REFERENCE TO RELATED APPLICATIONS

This application claims priority to Korean Patent Application No. 10-2025-0026352, filed on February 28, 2025, and Korean Patent Application No. 10-2025-0066805, filed on May 22, 2025, and all the benefits accruing therefrom under 35 U.S.C. §119, the contents of which in their entirety are herein incorporated by reference .

### BACKGROUND

### 1. Field

The present disclosure relates to a window, a method of manufacturing the window, and an electronic device including the window. More particularly, the present disclosure relates to a window including a glass substrate that is chamfered, a method of manufacturing the window, in which the method includes a multi-chamfering process, and an electronic device including the window.

### 2. Description of Related Art

Multimedia electronic devices, such as televisions, mobile phones, tablet computers, navigation devices, and game devices, include an active area activated in response to electric signals. Such electronic devices may include a display panel that displays various image information through the active area to provide information to a user and further include a touch panel which senses pressure applied from the outside through the active area.

The electronic devices may include a window that effectively transmits image information from the display panel to the outside and protects the display panel from external impacts.

### SUMMARY

The present disclosure provides a window with excellent print quality and impact resistance in a bezel area.

The present disclosure provides a method of manufacturing the window with excellent print quality and impact resistance in the bezel area.

The present disclosure provides an electronic device including the window having excellent print quality and impact resistance in the bezel area and provided with improved reliability.

Embodiments of the inventive concept provide a window including a transmission area and a bezel area surrounding the transmission area. The window includes a base substrate including an upper surface, a lower surface opposite to the upper surface, and a side surface connecting the upper surface and the lower surface and a bezel pattern disposed under the base substrate and overlapping the bezel area. The side surface includes a first side surface parallel to a thickness direction of the base substrate, a second side surface extending from the first side surface and connected to the lower surface, and a third side surface extending from the first side surface and connected to the upper surface. The second side surface includes a second-first side surface adjacent to the first side surface and a second-second side surface adjacent to the lower surface. An obtuse angle between the lower surface and the second-second side surface is greater than about 135 degrees.

An obtuse angle between the second-first side surface and the second-second side surface is greater than about 135 degrees.

A boundary at which the first side surface meets the second-first side surface includes a curved surface, and a boundary at which the second-first side surface meets the second-second side surface includes a curved surface.

The obtuse angle between the lower surface and the second-second side surface is greater than an obtuse angle between the first side surface and the second-first side surface.

An obtuse angle between the second-first side surface and the second-second side surface is greater than the obtuse angle between the first side surface and the second-first side surface.

The base substrate has a thickness smaller than or equal to about 1mm.

The third side surface includes a third-first side surface adjacent to the first side surface and a third-second side surface adjacent to the upper surface.

An obtuse angle between the upper surface and the third-second side surface is greater than about 135 degrees, and an obtuse angle between the third-first side surface and the third-second side surface is greater than about 135 degrees.

A boundary at which the first side surface meets the third-first side surface includes a curved surface, and a boundary at which the third-first side surface meets the third-second side surface includes a curved surface.

The bezel pattern is disposed directly on a portion of the lower surface and a portion of the side surface.

Embodiments of the inventive concept provide a method of manufacturing a window. The method includes providing a first preliminary glass substrate including an upper surface, a lower surface opposite to the upper surface, and a first side surface connecting the upper surface and the lower surface and perpendicular to the upper surface and the lower surface, forming a second preliminary glass substrate by first-chamfering the first preliminary glass substrate, the second preliminary glass substrate including a second preliminary side surface connecting the lower surface and the first side surface, and forming a third preliminary glass substrate by second-chamfering the second preliminary glass substrate, the third preliminary glass substrate including a second-first side surface adjacent to the first side surface and a second-second side surface connecting the second-first side surface and the lower surface.

The forming of the third preliminary glass substrate is performed by chamfering an edge defined by the lower surface and the second preliminary side surface of the second preliminary glass substrate. Based on the chamfering of the edge, each of an obtuse angle between the lower surface and the second-second side surface of the third preliminary glass substrate and an obtuse angle between the second-second side surface and the second-first side surface of the third preliminary glass substrate is greater than an obtuse angle between the first side surface and the second-first side surface.

The method further includes forming a base substrate, and the forming of the base substrate includes polishing the third preliminary glass substrate such that a boundary at which the first side surface meets the second-first side surface includes a curved surface and a boundary at which the second-first side surface meets the second-second side surface of the base substrate includes a curved surface.

The method further includes forming a bezel pattern in a portion of a lower surface of the base substrate.

The forming of the third preliminary glass substrate is performed such that the obtuse angle between the lower surface and the second-second side surface of the third preliminary glass substrate is greater than about 135 degrees.

Embodiments of the inventive concept provide an electronic device including a display panel including a display area and a non-display area surrounding the display area and a window disposed on the display panel and including a transmission area overlapping the display area and a bezel area overlapping the non-display area. The window includes a base substrate including an upper surface, a lower surface opposite to the upper surface, and a side surface connecting the upper surface and the lower surface and a bezel pattern disposed under the base substrate and overlapping the bezel area. The side surface includes a first side surface parallel to a thickness direction of the base substrate, a second side surface extending from the first side surface and connected to the lower surface, and a third side surface extending from the first side surface and connected to the upper surface. The second side surface includes a second-first side surface adjacent to the first side surface and a second-second side surface adjacent to the lower surface, and an obtuse angle between the lower surface and the second-second side surface is greater than about 135 degrees.

A boundary at which the first side surface meets the second-first side surface includes a curved surface, and a boundary at which the second-first side surface meets the second-second side surface includes a curved surface.

The obtuse angle between the lower surface and the second-second side surface is greater than an obtuse angle between the first side surface and the second-first side surface.

The electronic device further includes at least one of a processor, a memory, or a power module.

The electronic device is a television, a monitor, an outdoor billboard, a personal computer, a notebook computer, a personal digital assistant, a car dashboard, a center fascia, a navigation unit, a room mirror display, a game unit, a smartphone, a tablet computer, a smart watch, a smart glasses, a head-mounted display, or a camera.

According to the above, the glass substrate included in the window is processed with a multi-chamfering process, and as a result, the glass substrate exhibits excellent print quality for the ink layer in the bezel area and superior impact resistance against external impacts.

In some aspects, the method of manufacturing the window includes the multi-chamfering process, and thus, the window with excellent print quality in the bezel area and excellent impact resistance is manufactured.

Further, the electronic device includes the window having excellent print quality for the ink layer in the bezel area and excellent impact resistance against external impacts, and thus, reliability of the electronic device is improved.

### BRIEF DESCRIPTION OF THE DRAWINGS

FIG. 1 is a block diagram of an electronic device according to an embodiment of the present disclosure;

FIG. 2 is a schematic view of various electronic devices according to embodiments of the present disclosure;

FIG. 3 is an assembled perspective view of an electronic device according to an embodiment of the present disclosure;

FIG. 4 is an exploded perspective view of an electronic device according to an embodiment of the present disclosure;

FIG. 5 is a cross-sectional view of an electronic device according to an embodiment of the present disclosure;

FIG. 6 is a cross-sectional view of a display module according to an embodiment of the present disclosure;

FIG. 7 is a flowchart of a method of manufacturing a window according to an embodiment of the present disclosure;

FIGS. 8A to 11B are schematic views of processes of a manufacturing method of a window according to an embodiment of the present disclosure;

FIGS. 12A to 12D are enlarged cross-sectional views of windows according to embodiments of the present disclosure; and

FIGS. 13A to 13D are enlarged cross-sectional views of windows according to comparative examples.

### DETAILED DESCRIPTION

In the present disclosure, it will be understood that when an element (or area, layer, or portion) is referred to as being "on", "connected to" or "coupled to" another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, and the like may be used herein to describe various elements, these elements should not be limited by these terms. These terms are used to distinguish one element from another element. Thus, a first element discussed below could be termed a second element without departing from the teachings of the present disclosure. As an example, without departing from the scope of the present disclosure, a first component, a first part, a first region, a first layer, and a first portion are referred to as a second component, a second part, a second region, a second layer, and a second portion, respectively, and vice versa. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another elements or features as illustrated in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ± 30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

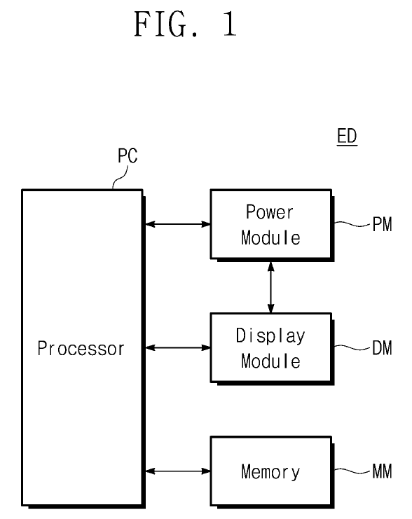

FIG. 1 is a block diagram of an electronic device according to an embodiment of the present disclosure.

FIG. 1, the electronic device ED may include a display module DM, a processor PC, a memory MM, and a power module PM.

The processor PC may include at least one of a central processing unit (CPU), an application processor (AP), a graphics processing unit (GPU), a communication processor (CP), an image signal processor (ISP), and a controller.

The memory MM may store data information supportive of the operation of the processor PC or the display module DM. In an example in which the processor PC executes an application stored in the memory MM, an image data signal and/or an input control signal may be transmitted to the display module DM, and the display module DM may process the received signals to output image information through a display screen.

The power module PM may include a power supply module, such as a power adapter or a battery device, and a power conversion module that converts power supplied by the power supply module to generate power for the operation of the electronic device ED.

At least one of the above-described components of the electronic device ED may be included in electronic devices according to embodiments described herein. In some aspects, among individual modules that are functionally included within a single module, some may be included in the electronic device ED while others may be provided separately from the electronic device ED. As an example, the electronic device ED may include the display module DM, and the processor PC, the memory MM, and the power module PM may be provided as separate devices other than the electronic device ED.

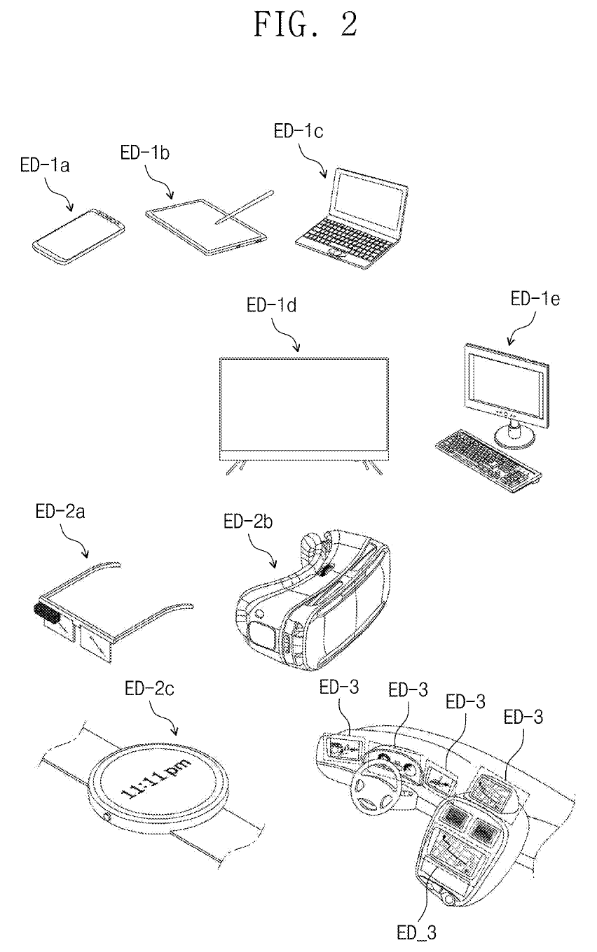

FIG. 2 is a schematic view illustrating various electronic devices according to embodiments of the present disclosure.

Referring to FIG. 2, various electronic devices to which the display module according to the embodiment of the present disclosure is applied may include not only an electronic device to display images, such as a smartphone ED-1a, a tablet PC ED-1b, a laptop computer ED-1c, a television ED-1d, a desktop monitor ED-1e, or the like, but also a wearable electronic device, such as a smart glasses ED-2a, a head-mounted display ED-2b, a smartwatch ED-2c, or the like, and an in-vehicle electronic device ED-3, such as an instrument panel, a center fascia, a dashboard-mounted center information display (CID), or a room mirror display.

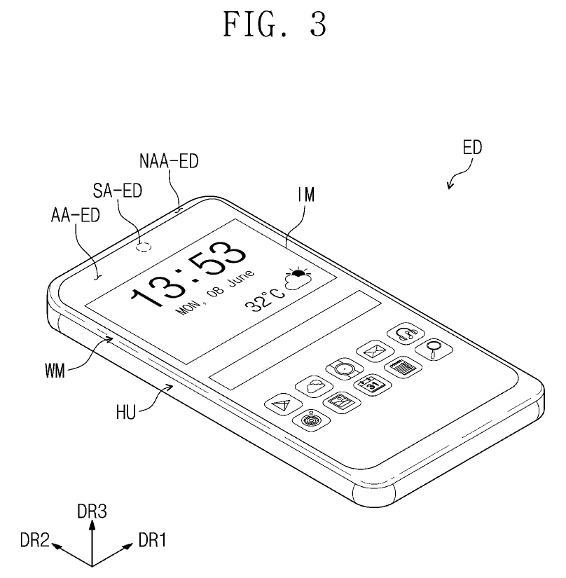

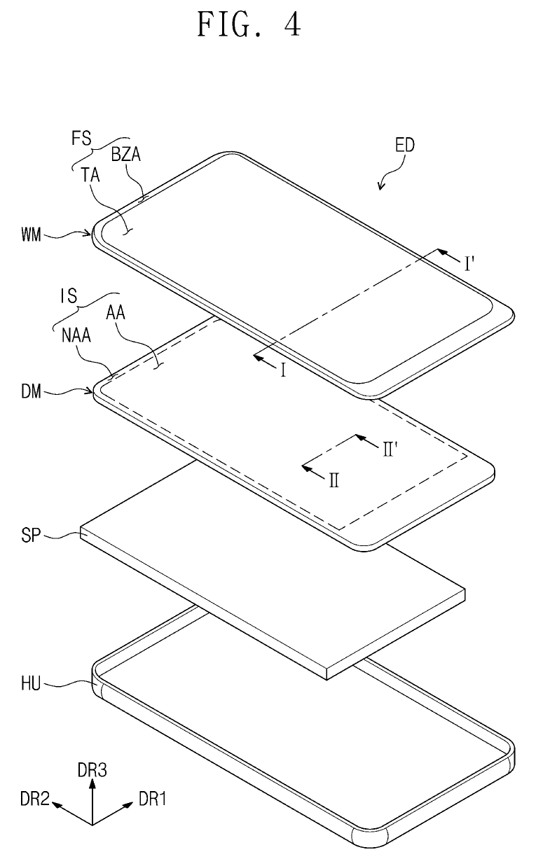

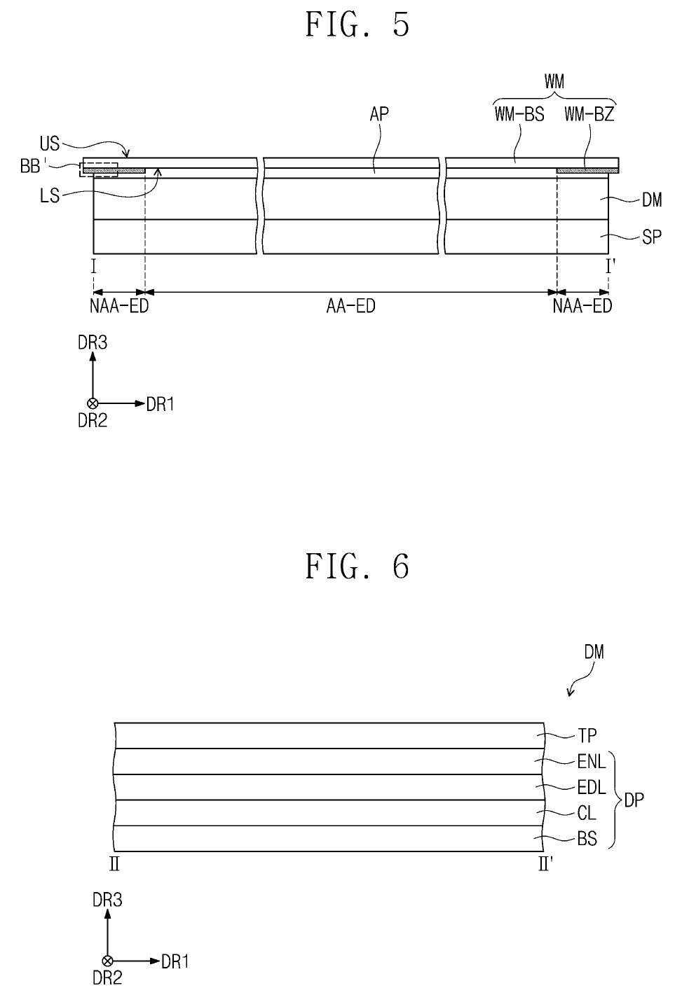

FIG. 3 is an assembled perspective view of the electronic device according to an embodiment of the present disclosure. FIG. 4 is an exploded perspective view of the electronic device according to an embodiment of the present disclosure. FIG. 5 is a cross-sectional view of the electronic device according to an embodiment of the present disclosure. FIG. 5 is a cross-sectional view schematically illustrating a portion of some components of the electronic device ED of FIG. 4, which is taken along a line I-I’.

The electronic device ED may be activated in response to electrical signals. The electronic device ED may be a television, a monitor, an outdoor billboard, a personal computer, a notebook computer, a personal digital assistant, a car dashboard, a center fascia, a navigation unit, a room mirror display, a game unit, a smartphone, a tablet computer, a smart watch, a smart glasses, a head-mounted display, or a camera, however, the present disclosure should not be limited thereto or thereby. FIG. 3 illustrates the smartphone as a representative example of the electronic device ED.

The electronic device ED may include an active area AA-ED and a peripheral area NAA-ED. An image IM may be displayed through the active area AA-ED of the electronic device ED. The image IM may include a still image as well as a video. FIG. 3 illustrates a clock widget and application icons as representative examples of the image IM. The active area AA-ED of the electronic device ED may correspond to a display area AA of the display module DM, and the peripheral area NAA-ED may correspond to a non-display area NAA of the display module DM. The active area AA-ED of the electronic device ED may correspond to a transmission area TA of a window WM, and the peripheral area NAA-ED may correspond to a bezel area BZA of the window WM.

The electronic device ED may display the image IM in a direction corresponding to a third directional axis DR3 through a display surface substantially parallel to a plane defined by a first directional axis DR1 and a second directional axis DR2. The display surface through which the image IM is displayed may correspond to a front surface of the electronic device ED and an upper surface FS of the window WM. In some aspects, the electronic device ED may have a three-dimensional shape with a selected thickness in the direction corresponding to the third directional axis DR3, which is perpendicular to the plane defined by the first directional axis DR1 and the second directional axis DR2.

In the present disclosure, upper (or front) and lower (or rear) surfaces of each member may be defined with respect to a direction in which the image IM is displayed. The front surface and the rear surface may be opposite to each other in the third directional axis DR3, and a normal line direction of each of the front and rear surfaces may be substantially parallel to the third directional axis DR3. Directions indicated by the first, second, and third directional axes DR1, DR2, and DR3 may be relative to each other, and thus, the directions indicated by the first, second, and third directional axes DR1, DR2, and DR3 may be changed to other directions. Hereinafter, first, second, and third directions may refer to the directions indicated by the first, second, and third directional axes DR1, DR2, and DR3, respectively, with the same reference numerals.

The electronic device ED may sense an external input applied from the outside. The external input may include inputs of various forms, such as force, pressure, temperature, light, or the like. The external input may be a touch input generated by a user’s hand and applied to the front surface of the electronic device ED. The external input may include all types of inputs that cause a variation in capacitance of a touch panel TP (refer to FIG. 6). The area of the electronic device ED that senses the external input should not be limited to the front surface of the electronic device ED, and the electronic device ED may sense the external input by the user applied to a side or rear surface thereof depending on a structure of the electronic device ED.

The active area AA-ED may have a rectangular shape parallel to the plane defined by the first directional axis DR1 and the second directional axis DR2. However, this is an example, and the active area AA-ED may have various shapes and should not be particularly limited.

The peripheral area NAA-ED may be a light blocking area that is located outside the active area AA-ED and surrounds the active area AA-ED. In an embodiment, the peripheral area NAA-ED may be disposed on the side surface instead of the front surface of the electronic device ED. In an embodiment, the peripheral area NAA-ED may be omitted.

A sensing area SA-ED may be defined in the active area AA-ED of the electronic device ED. FIG. 3 illustrates one sensing area SA-ED as a representative example, however, the number of sensing areas SA-ED should not be limited thereto or thereby.

An electronic module may be disposed in an area overlapping with the sensing area SA-ED. The electronic module may receive an external input transmitted through the sensing area SA-ED or may provide an output through the sensing area SA-ED.

The electronic device ED may be flexible. The term “flexible” used herein refers to the property of being able to be bent, and the electronic device ED may include all structures from a structure that is completely bent to a structure that is bent at the scale of a few nanometers. For example, the electronic device ED may be a curved display device, a rollable display device, a slidable display device, or a foldable display device. Alternatively, the electronic device ED may be rigid.

The electronic device ED may include the display module DM. The electronic device ED may further include the window WM disposed on the display module DM. Further, the electronic device ED may further include a support member SP and/or a housing HU disposed under the display module DM. In the electronic device ED illustrated in FIGS. 3 and 4, the window WM and the housing HU may be coupled to each other to form the exterior of the electronic device ED. Although not illustrated in figures, a through-hole may be defined through the support member SP and the display module DM in an overlapping manner with the electronic module.

In the electronic device ED, the window WM may be disposed on the display module DM. The window WM may include a base substrate WM-BS and a bezel pattern WM-BZ.

The base substrate WM-BS may include an optically transparent insulating material. The base substrate WM-BS may include a glass substrate. Functional layers, such as an anti-reflective layer, an anti-fingerprint layer, an optical layer controlling a phase, or the like, may be further disposed on the base substrate WM-BS.

The bezel pattern WM-BZ may be a colored layer printed on one surface of the base substrate WM-BS or a colored layer deposited on the base substrate WM-BS. As an example, the bezel pattern WM-BZ may have a multi-layer structure. The bezel pattern WM-BZ having the multi-layer structure may include a chromatic color layer and/or a light blocking layer having a black color. The chromatic color layer and/or the light blocking layer having the black color may be formed through a depositing, printing, or coating process.

The window WM includes the upper surface FS that is exposed to the outside. The transmission area TA on the upper surface FS of the window WM may be an optically transparent area. The transmission area TA may have a shape corresponding to the display area AA of the display module DM. For example, the transmission area TA may overlap with an entire portion or at least a portion of the display area AA. An image displayed through the display area AA of the display module DM may be visible from the outside through the transmission area TA.

The bezel area BZA of the window WM may be adjacent to the transmission area TA and may surround the transmission area TA. The bezel area BZA may cover the non-display area NAA of the display module DM to prevent the non-display area NAA from being visible from the outside.

The base substrate WM-BS may include a lower surface LS adjacent to the display module DM and an upper surface US opposite to the lower surface LS. In an embodiment, the upper surface US of the base substrate WM-BS may correspond to the upper surface FS of the electronic device ED.

The bezel pattern WM-BZ may be disposed on the lower surface LS of the base substrate WM-BS.

The electronic device ED may include at least one adhesive layer AP. The adhesive layer AP may include a transparent adhesive, such as an optically clear adhesive (OCA) film, an optically clear resin (OCR), a pressure sensitive adhesive (PSA) film, or the like, but embodiments of the present disclosure are not limited thereto. According to an embodiment, different from the electronic device ED illustrated in FIG. 5, the adhesive layer AP may be omitted.

In the electronic device ED according to the embodiment, the electronic module may be an electronic component that outputs or receives optical signals. For example, the electronic module may be a camera module that captures images of external objects. In some aspects, the electronic module may be a sensor module, such as a proximity sensor or an infrared light emitting sensor.

The display module DM may include the display area AA and the non-display area NAA adjacent to the display area AA. That is, a front surface IS of the display module DM may include the display area AA and the non-display area NAA. The display area AA may be activated in response to electrical signals.

The non-display area NAA may be adjacent to the display area AA. The non-display area NAA may surround the display area AA. Driving circuits or driving wirings to drive the display area AA, various signal lines or pads to provide electrical signals to the display area AA, or electronic components, or the like, may be arranged in the non-display area NAA.

The support member SP disposed under the display module DM may include a cushion layer and/or a metal support layer.

The window WM may be coupled to the housing HU to define an exterior of the electronic device ED. The window WM may be coupled to the housing HU to form an inner space to accommodate components of the display module DM. The display module DM, the support member SP, and the electronic module may be accommodated in the inner space.

The housing HU may include a material with a relatively high rigidity. As an example, the housing HU may include a frame and/or a plate formed of glass, plastic, metal material, or combinations thereof. The housing HU may absorb external impacts applied thereto from the outside and may prevent a foreign substance or moisture from entering therein to protect the display module DM.

FIG. 6 is a cross-sectional view of the display module DM according to an embodiment of the present disclosure. FIG. 6 is a cross-sectional view taken along a line II-II’ of FIG. 4.

The display module DM may include a display panel DP and a touch panel TP disposed on the display panel DP. The display panel DP may include a base layer BS, a circuit layer CL disposed on the base layer BS, a light emitting element layer EDL disposed on the circuit layer CL, and an encapsulation layer ENL disposed on the light emitting element layer EDL. The touch panel TP may be disposed on the encapsulation layer ENL. The encapsulation layer ENL may cover the light emitting element layer EDL.

The base layer BS may provide a base surface on which the light emitting element layer EDL is disposed. The base layer BS may be a glass substrate, a metal substrate, or a polymer substrate, however, embodiments of the present disclosure are not limited thereto. According to an embodiment, the base layer BS may be an inorganic layer, an organic layer, or a composite material layer.

The base layer BS may have a multi-layer structure. The base layer BS may have a three-layer structure of a synthetic resin layer, an adhesive layer, and a synthetic resin layer. In particular, the synthetic resin layer may include a polyimide-based resin layer. In some aspects, the synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. In the present disclosure, the term “A-based resin” means that a functional group of “A” is included.

The circuit layer CL may be disposed on the base layer BS. The circuit layer CL may include an insulating layer, a semiconductor pattern, a conductive pattern, and a signal line. An insulating layer, a semiconductor layer, and a conductive layer may be formed on the base layer BS by a coating or depositing process. Then, the insulating layer, the semiconductor layer, and the conductive layer may be selectively patterned through several photolithography processes. Thus, the semiconductor pattern, the conductive pattern, and the signal line of the circuit layer CL may be formed. The circuit layer CL will be described in detail later.

The light emitting element layer EDL may be disposed on the circuit layer CL. The light emitting element layer EDL may include a light emitting element. As an example, the light emitting element layer EDL may include an organic light emitting element, an inorganic light emitting element, a quantum dot light emitting element, a micro-LED, or a nano-LED, an electrophoretic element, or an electrowetting element.

The light emitting element of the light emitting element layer EDL may be disposed in the display area AA (refer to FIG. 4). The light emitting element may not be disposed in the non-display area NAA.

The encapsulation layer ENL may be disposed on the light emitting element layer EDL. The encapsulation layer ENL may include at least one inorganic layer and at least one organic layer. As an example, the encapsulation layer ENL may include an inorganic layer, an organic layer, and an inorganic layer, which are sequentially stacked, however, layers constituting the encapsulation layer ENL should not be limited thereto or thereby.

The touch panel TP may be disposed on the display panel DP. The touch panel TP may sense the external input applied from the outside. The external input may be an input generated by the user. The input generated by the user may include various forms of external input, such as a part of the user's body, light, heat, a pen, or pressure. In an embodiment, the touch panel TP may be omitted.

The touch panel TP may be formed on the display panel DP through a continuous process. In this case, the touch panel TP may be described as being disposed directly on the display panel DP. In the present disclosure, the expression “the touch panel TP may be disposed directly on the display panel DP” means that no other component is disposed between the touch panel TP and the display panel DP. That is, a separate adhesive member may not be disposed between the touch panel TP and the display panel DP. For example, the touch panel TP may be disposed directly on the encapsulation layer ENL.

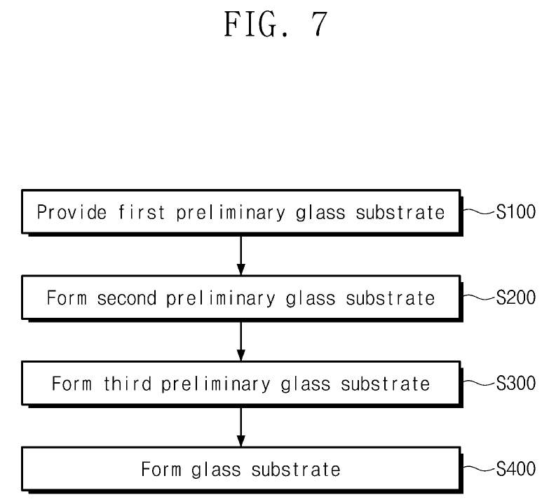

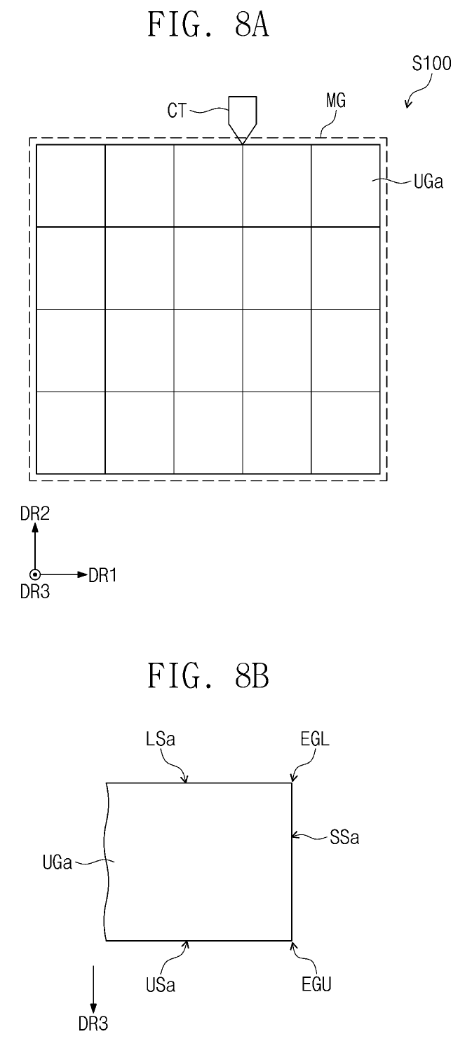

FIG. 7 is a flowchart of a method of manufacturing a window according to an embodiment of the present disclosure. FIGS. 8A to 11B are schematic views of processes of the manufacturing method of the window according to an embodiment of the present disclosure.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added.

The method of manufacturing the window may include providing a glass substrate and forming an ink layer on the glass substrate.

Referring to FIG. 7, the providing of the glass substrate may include providing a first preliminary glass substrate (S100), forming a second preliminary glass substrate (S200), forming a third preliminary glass substrate (S300), and forming the glass substrate (S400).

FIG. 8A is a plan view schematically illustrating the providing of the first preliminary glass substrate UGa (S100) according to an embodiment of the present disclosure, and FIG. 8B is a cross-sectional view schematically illustrating the first preliminary glass substrate UGa provided according to an embodiment of the present disclosure.

Referring to FIG. 8A, the providing of the first preliminary glass substrate UGa (S100) may include cutting a mother substrate MG. The mother substrate MG may be cut by a cutter CT, and then, a plurality of unit glass substrates may be provided. Each of the unit glass substrates may be referred to as the first preliminary glass substrate UGa.

The mother substrate MG may be a raw glass substrate. The mother substrate MG may have a thickness smaller than or equal to about 1mm. As an example, the thickness of the mother substrate MG may range from about 0.4mm to about 0.6mm. The cutter CT may be a cutting wheel.

FIG. 8B is a cross-sectional view illustrating one end of the first preliminary glass substrate UGa. The first preliminary glass substrate UGa may include an upper surface USa, a lower surface LSa, and a side surface SSa.

The upper surface USa of the first preliminary glass substrate UGa may be perpendicular to the third direction DR3. The upper surface USa of the first preliminary glass substrate UGa may be substantially parallel to the plane defined by the first direction DR1 and the second direction DR2.

The lower surface LSa of the first preliminary glass substrate UGa may be opposite to the upper surface USa. The lower surface LSa of the first preliminary glass substrate UGa may be substantially parallel to the plane defined by the first direction DR1 and the second direction DR2. The lower surface LSa of the first preliminary glass substrate UGa may be substantially parallel to the upper surface USa.

The side surface SSa of the first preliminary glass substrate UGa may connect the upper surface USa and the lower surface LSa. The side surface SSa of the first preliminary glass substrate UGa may be perpendicular to the plane defined by the first direction DR1 and the second direction DR2. The side surface SSa of the first preliminary glass substrate UGa may be perpendicular to each of the upper surface USa and the lower surface LSa. The side surface SSa of the first preliminary glass substrate UGa may be substantially parallel to a thickness direction of the first preliminary glass substrate UGa. The side surface SSa of the first preliminary glass substrate UGa may be substantially parallel to the third direction DR3.

As the first preliminary glass substrate UGa is cut by the cutter CT, the first preliminary glass substrate UGa may include cracks in a portion adjacent to its edge. In some aspects, the first preliminary glass substrate UGa may include an edge EGU where the upper surface USa meets the side surface SSa and an edge EGL where the lower surface LSa meets the side surface SSa. Since the edges EGU and EGL of the first preliminary glass substrate UGa protrude, stress may be concentrated at the edges EGU and EGL when the external impact is applied. That is, since the cracks occur in the first preliminary glass substrate UGa and the edges EGU and EGL protrude, the first preliminary glass substrate UGa may be vulnerable to the external impact.

The first preliminary glass substrate UGa may have a thickness smaller than or equal to about 1mm. As an example, the thickness of the first preliminary glass substrate UGa may range from about 0.4mm to about 0.6mm.

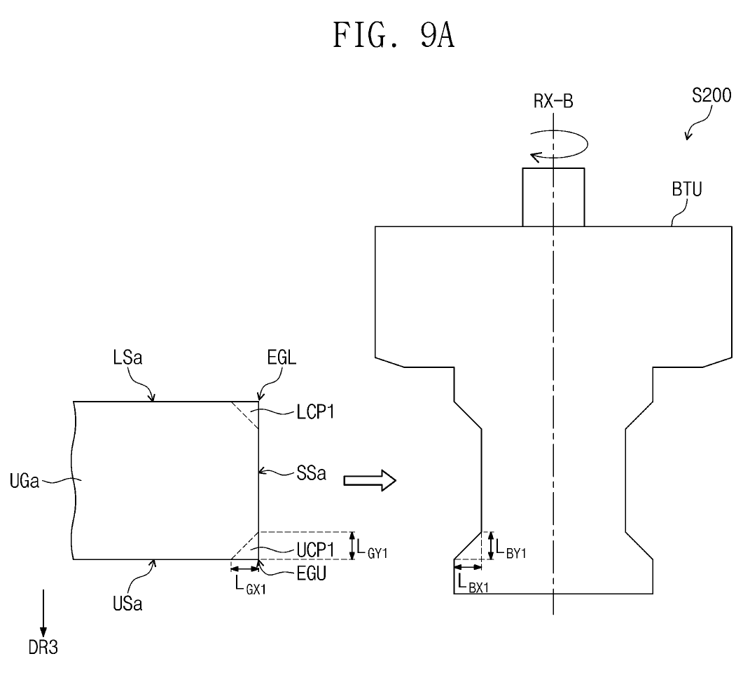

FIG. 9A is a plan view schematically illustrating the forming of the second preliminary glass substrate UGb (S200) according to an embodiment of the present disclosure, and FIG. 9B is a cross-sectional view schematically illustrating the second preliminary glass substrate UGb provided according to an embodiment of the present disclosure.

Referring to FIG. 9A, the forming of the second preliminary glass substrate UGb (S200) may include a process of first-chamfering the first preliminary glass substrate UGa. The first preliminary glass substrate UGa may be first-chamfered by a bit BTU.

The bit BTU may rotate around a bit rotation axis RX-B to chamfer the first preliminary glass substrate UGa. The bit rotation axis RX-B may be parallel to the thickness direction DR3 of the first preliminary glass substrate UGa. The bit BTU may include a first groove having a shape that corresponds to a shape of a portion of the first preliminary glass substrate UGa to be chamfered.

Portions of the first preliminary glass substrate UGa to be chamfered may be defined as first chamfered portions LCP1 and UCP1. The first chamfered portions LCP1 and UCP1 may correspond to the portion where the lower surface LSa and the side surface SSa of the first preliminary glass substrate UGa meet and the portion where the upper surface USa and the side surface SSa of the first preliminary glass substrate UGa meet, respectively. The first chamfered portions LCP1 and UCP1 may have an isosceles triangle in a cross-section. For example, lengths L_{GX1} and L_{GY1} of equal sides (or legs) of the isosceles triangle of the first chamfered portions LCP1 and UCP1 may be about 0.1mm.

The first groove included in the bit BTU may be defined by an isosceles triangle corresponding to the first chamfered portions LCP1 and UCP1. For example, lengths L_{GX1} and L_{GY1} of equal sides (or legs) of the isosceles triangle of the first groove included in the bit BTU may be about 0.1mm.

FIG. 9B is a cross-sectional view illustrating one end of the second preliminary glass substrate UGb. The second preliminary glass substrate UGb may include an upper surface USb, a lower surface LSb, and a side surface SSb.

The upper surface USb of the second preliminary glass substrate UGb may be perpendicular to the third direction DR3. The upper surface USb of the second preliminary glass substrate UGb may be parallel to the plane defined by the first direction DR1 and the second direction DR2. The upper surface USb of the second preliminary glass substrate UGb may be a surface remaining after the upper surface USa of the first preliminary glass substrate UGa is chamfered.

The lower surface LSb of the second preliminary glass substrate UGb may be opposite to the upper surface USb. The lower surface LSb of the second preliminary glass substrate UGb may be parallel to the plane defined by the first direction DR1 and the second direction DR2. The lower surface LSb of the second preliminary glass substrate UGb may be parallel to the upper surface USb. The lower surface LSb of the second preliminary glass substrate UGb may be a surface remaining after the lower surface LSa of the first preliminary glass substrate UGa is chamfered.

The side surface SSb of the second preliminary glass substrate UGb may connect the upper surface USb and the lower surface LSb. The side surface SSb of the second preliminary glass substrate UGb may include a first side surface SS1b, a second side surface SS2b, and a third side surface SS3b. The side surface SSb of the second preliminary glass substrate UGb may be referred to as a second preliminary side surface.

The first side surface SS1b of the second preliminary glass substrate UGb may be perpendicular to each of the upper surface USb and the lower surface LSb. The first side surface SS1b of the second preliminary glass substrate UGb may be parallel to a thickness direction of the second preliminary glass substrate UGb. The first side surface SS1b of the second preliminary glass substrate UGb may be parallel to the third direction DR3. The first side surface SS1b of the second preliminary glass substrate UGb may be a surface remaining after the side surface SSa of the first preliminary glass substrate UGa is chamfered.

The second side surface SS2b of the second preliminary glass substrate UGb may extend from the first side surface SS1b and may be connected to the lower surface LSb. An obtuse angle between the second side surface SS2b and the lower surface LSb of the second preliminary glass substrate UGb may be about 135 degrees. An obtuse angle between the second side surface SS2b and the first side surface SS1b of the second preliminary glass substrate UGb may be about 135 degrees.

The third side surface SS3b of the second preliminary glass substrate UGb may extend from the first side surface SS1b and may be connected to the upper surface USb. An obtuse angle between the third side surface SS3b and the upper surface USb of the second preliminary glass substrate UGb may be about 135 degrees. An obtuse angle between the third side surface SS3b and the first side surface SS1b of the second preliminary glass substrate UGb may be about 135 degrees.

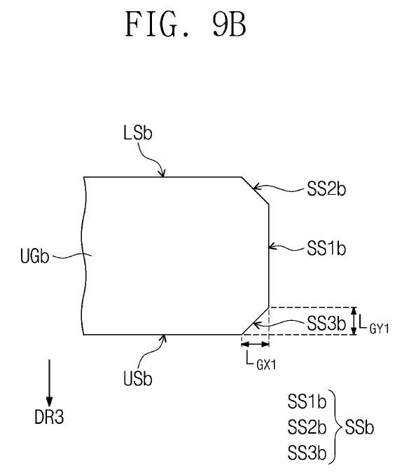

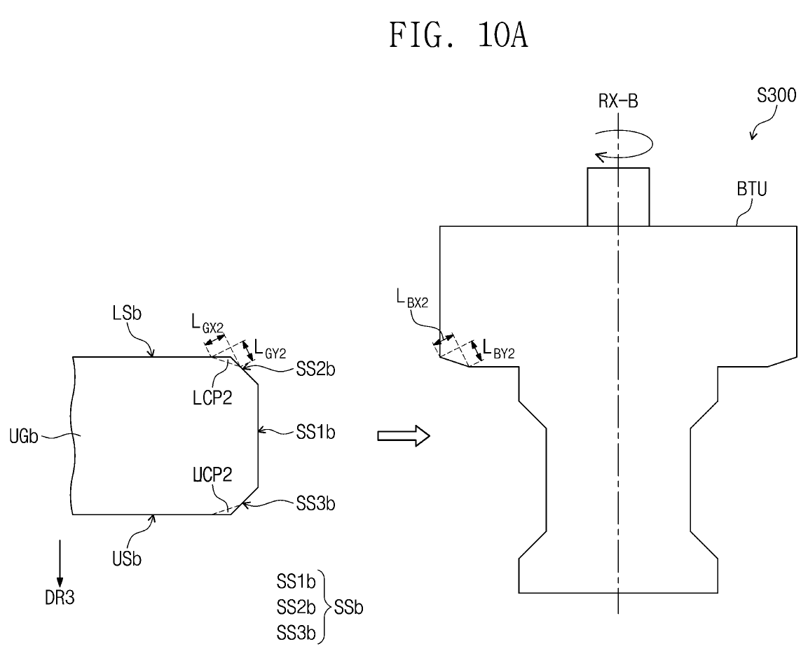

FIG. 10A is a plan view schematically illustrating the forming of the third preliminary glass substrate UGc (S300) according to an embodiment of the present disclosure, and FIG. 10B is a cross-sectional view schematically illustrating the third preliminary glass substrate UGc provided according to an embodiment of the present disclosure.

Referring to FIG. 10A, the forming of the third preliminary glass substrate UGc (S300) may include a process of second-chamfering the second preliminary glass substrate UGb. The second preliminary glass substrate UGb may be second-chamfered by the bit BTU.

The bit BTU may rotate around the bit rotation axis RX-B to chamfer the second preliminary glass substrate UGb. The bit rotation axis RX-B may be parallel to the thickness direction DR3 of the second preliminary glass substrate UGb. The bit BTU may include a second groove having a shape corresponding to a shape of a portion of the second preliminary glass substrate UGb to be chamfered.

Portions of the second preliminary glass substrate UGb to be chamfered may be defined as second chamfered portions LCP2 and UCP2. The second chamfered portions LCP2 and UCP2 may correspond to the portion where the lower surface LSb and the side surface SS2b of the second preliminary glass substrate UGb meet and the portion where the upper surface USb and the third side surface SS3b of the second preliminary glass substrate UGb meet, respectively. The second chamfered portions LCP2 and UCP2 may have an isosceles triangle in a cross-section.

The second groove included in the bit BTU may have a shape corresponding to a base of the isosceles triangle corresponding to the second chamfered portions LCP2 and UCP2. The second groove may have a right isosceles triangle that includes a base corresponding to the base of the isosceles triangle corresponding to the second chamfered portions LCP2 and UCP2. For example, lengths L_{BX1} and L_{BY1} of equal sides (or legs) of the right isosceles triangle of the second groove included in the bit BTU may be about 0.05mm.

FIG. 10B is a cross-sectional view illustrating one end of the third preliminary glass substrate UGc. The third preliminary glass substrate UGc may include an upper surface USc, a lower surface LSc, and a side surface SSc.

The upper surface USc of the third preliminary glass substrate UGc may be perpendicular to the third direction DR3. The upper surface USc of the third preliminary glass substrate UGc may be parallel to the plane defined by the first direction DR1 and the second direction DR2. The upper surface USc of the third preliminary glass substrate UGc may be a surface remaining after the upper surface USb of the second preliminary glass substrate UGb is chamfered.

The lower surface LSc of the third preliminary glass substrate UGc may be opposite to the upper surface USc. The lower surface LSc of the third preliminary glass substrate UGc may be parallel to the plane defined by the first direction DR1 and the second direction DR2. The lower surface LSc of the third preliminary glass substrate UGc may be parallel to the upper surface USc. The lower surface LSc of the third preliminary glass substrate UGc may be a surface remaining after the lower surface LSb of the second preliminary glass substrate UGb is chamfered.

The side surface SSc of the third preliminary glass substrate UGc may connect the upper surface USc and the lower surface LSc. The side surface SSc of the third preliminary glass substrate UGc may include a first side surface SS1c, a second side surface SS2c, and a third side surface SS3c.

The first side surface SS1c of the third preliminary glass substrate UGc may be perpendicular to each of the upper surface USc and the lower surface LSc. The first side surface SS1c of the third preliminary glass substrate UGc may be parallel to a thickness direction of the third preliminary glass substrate UGc. The first side surface SS1c of the third preliminary glass substrate UGc may be parallel to the third direction DR3. Since the first side surface SS1c of the third preliminary glass substrate UGc is not chamfered, the first side surface SS1c may have the same shape as the shape of the first side surface SS1b of the second preliminary glass substrate UGb.

The second side surface SS2c of the third preliminary glass substrate UGc may extend from the first side surface SS1c and may be connected to the lower surface LSc. The second side surface SS2c of the third preliminary glass substrate UGc may include a second-first side surface SS2-1c and a second-second side surface SS2-2c.

The second-first side surface SS2-1c of the third preliminary glass substrate UGc may be a surface remaining after the second side surface SS2b of the second preliminary glass substrate UGb is chamfered. An obtuse angle between the second-first side surface SS2-1c and the first side surface SS1c of the third preliminary glass substrate UGc may be about 135 degrees.

The second-second side surface SS2-2c of the third preliminary glass substrate UGc may extend from the second-first side surface SS2-2c and may be connected to the lower surface LSc. The second-second side surface SS2-2c of the third preliminary glass substrate UGc may be a surface formed by chamfering the second side surface SS2b of the second preliminary glass substrate UGb. An obtuse angle between the second-second side surface SS2-2c and the lower surface LSc of the third preliminary glass substrate UGc may be greater than the obtuse angle between the second-first side surface SS2-1c and the first side surface SS1c . The obtuse angle between the second-second side surface SS2-2c and the lower surface LSc of the third preliminary glass substrate UGc may be greater than about 135 degrees. As an example, the obtuse angle between the second-second side surface SS2-2c and the lower surface LSc of the third preliminary glass substrate UGc may be about 157.5 degrees. An obtuse angle between the second-second side surface SS2-2c and the second-first side surface SS2-1c of the third preliminary glass substrate UGc may be greater than the obtuse angle between the second-first side surface SS2-1c and the first side surface S1c. The obtuse angle between the second-second side surface SS2-2c and the second-first side surface SS2-1c of the third preliminary glass substrate UGc may be greater than about 135 degrees. As an example, the obtuse angle between the second-second side surface SS2-2c and the second-first side surface SS2-1c of the third preliminary glass substrate UGc may be about 157.5 degrees.

The third side surface SS3c of the third preliminary glass substrate UGc may extend from the first side surface SS1c and may be connected to the upper surface USc. The third side surface SS3c of the third preliminary glass substrate UGc may include a third-first side surface SS3-1c and a third-second side surface SS3-2c.

The third-first side surface SS3-1c of the third preliminary glass substrate UGc may be a surface after the third side surface SS3b of the second preliminary glass substrate UGb is chamfered. An obtuse angle between the third-first side surface SS3-1c and the first side surface SS1c of the third preliminary glass substrate UGc may be about 135 degrees.

The third-second side surface SS3-2c of the third preliminary glass substrate UGc may extend from the third-first side surface SS3-1c and may be connected to the upper surface USc. The third-second side surface SS3-2c of the third preliminary glass substrate UGc may be a surface formed by chamfering the third side surface SS3b of the second preliminary glass substrate UGb. An obtuse angle between the third-second side surface SS3-2c and the upper surface USc of the third preliminary glass substrate UGc may be greater than the obtuse angle between the third-first side surface SS3-1c and the first side surface SS1c. The obtuse angle between the third-second side surface SS3-2c and the upper surface USc of the third preliminary glass substrate UGc may be greater than about 135 degrees. As an example, the obtuse angle between the third-second side surface SS3-2c and the upper surface USc of the third preliminary glass substrate UGc may be about 157.5. An obtuse angle between the third-second side surface SS3-2c and the third-first side surface SS3-1c of the third preliminary glass substrate UGc may be greater than the obtuse angle between the third-first side surface SS3-1c and the first side surface SS1c. The obtuse angle between the third-second side surface SS3-2c and the third-first side surface SS3-1c of the third preliminary glass substrate UGc may be greater than about 135 degrees. For example, the obtuse angle between the third-second side surface SS3-2c and the third-first side surface SS3-1c of the third preliminary glass substrate UGc may be about 157.5 degrees.

In an embodiment, the manufacturing method of the window may further include a process of third-chamfering the third preliminary glass substrate UGc in addition to the first and second-chamfering processes. As an example, in the case where the third preliminary glass substrate UGc is third chamfered, an edge portion where the lower surface LSc and the second-second side surface SS2-2c of the third preliminary glass substrate UGc meet and/or an edge portion where the upper surface USc and the third-second side surface SS3-2c meet may be chamfered.

FIG. 11A is a cross-sectional view schematically illustrating the forming of the glass substrate UGd (S400) according to an embodiment of the present disclosure, and FIG. 11B is a cross-sectional view schematically illustrating the glass substrate UGd formed according to an embodiment of the present disclosure.

Referring to FIG. 11A, the forming of the glass substrate UGd (S400) may include a process of polishing the third preliminary glass substrate UGc. The third preliminary glass substrate UGc may be polished by a brush BRU included in a polishing device PLS.

The polishing device PLS may include a rotation unit LTU. The brush BRU may be disposed on the rotation unit LTU. The polishing device PLS may rotate around a polishing rotation axis RX-P to polish the third preliminary glass substrate UGc. The polishing rotation axis RX-P may be parallel to the thickness direction DR3 of the third preliminary glass substrate UGc. Multiple third preliminary glass substrates UGc may be substantially simultaneously polished. The polishing device PLS may be provided in plural.

FIG. 11B is a cross-sectional view illustrating one end of the glass substrate UGd. The glass substrate UGd may include an upper surface USd, a lower surface LSd, and a side surface SSd.

The upper surface USd of the glass substrate UGd may be perpendicular to the third direction DR3. The upper surface USd of the glass substrate UGd may be parallel to the plane defined by the first direction DR1 and the second direction DR2. Since the upper surface USd of the glass substrate UGd is not be polished, the upper surface USd of the glass substrate UGd may have the same shape as the shape of the upper surface USc of the third preliminary glass substrate UGc.

The lower surface LSd of the glass substrate UGd may be opposite to the upper surface USd. The lower surface LSd of the glass substrate UGd may be parallel to the plane defined by the first direction DR1 and the second direction DR2. The lower surface LSd of the glass substrate UGd may be parallel to the upper surface USd. Since the lower surface LSd of the glass substrate UGd is not polished, the lower surface LSd of the glass substrate UGd may have the same shape as the shape of the lower surface LSc of the third preliminary glass substrate UGc.

The side surface SSd of the glass substrate UGd may connect the upper surface USd and the lower surface LSd. The side surface SSd of the glass substrate UGd may include a first side surface SS1d, a second side surface SS2d, and a third side surface SS3d.

The first side surface SS1d of the glass substrate UGd may be perpendicular to each of the upper surface USd and the lower surface LSd. The first side surface SS1d of the glass substrate UGd may be parallel to a thickness direction of the glass substrate UGd. The first side surface SS1d of the glass substrate UGd may be parallel to the third direction DR3. The first side surface SS1d of the glass substrate UGd may be a surface obtained by polishing the first side surface SS1c of the third preliminary glass substrate UGc.

The second side surface SS2d of the glass substrate UGd may extend from the first side surface SS1d and may be connected to the lower surface LSd. The second side surface SS2d of the glass substrate UGd may include a second-first side surface SS2-1d and a second-second side surface SS2-2d.

The second-first side surface SS2-1d of the glass substrate UGd may be a surface obtained by polishing the second-first side surface SS2-1c of the third preliminary glass substrate UGc. A portion where the second-first side surface SS2-1d and the first side surface SS1d of the glass substrate UGd meet may be a curved surface. An obtuse angle between the second-first side surface SS2-1d and the first side surface SS1d of the glass substrate UGd may be about 135 degrees. In the present embodiment, the obtuse angle between the second-first side surface SS2-1d and the first side surface SS1d of the glass substrate UGd may be an obtuse angle formed between a tangent line of the second-first side surface SS2-1d and a tangent line of the first side surface SS1d.

The second-second side surface SS2-2d of the glass substrate UGd may extend from the second-first side surface SS2-1d and may be connected to the lower surface LSd. The second-second side surface SS2-2d of the glass substrate UGd may be a surface obtained by polishing the second-second side surface SS2-2c of the third preliminary glass substrate UGc. An obtuse angle between the second-second side surface SS2-2d and the lower surface LSd of the glass substrate UGd may be greater than the obtuse angle between the second-first side surface SS2-1d and the first side surface SS1d. The obtuse angle between the second-second side surface SS2-2d and the lower surface LSd of the glass substrate UGd may be an obtuse angle formed between a tangent line of the second-second side surface SS2-2d and the lower surface LSd. The obtuse angle between the second-second side surface SS2-2d and the lower surface LSd of the glass substrate UGd may be greater than about 135 degrees. As an example, the obtuse angle between the second-second side surface SS2-2d and the lower surface LSd of the glass substrate UGd may be about 157.5 degrees. An obtuse angle between the second-second side surface SS2-2d and the second-first side surface SS2-1d of the glass substrate UGd may be greater than the obtuse angle between the second-first side surface SS2-1d and the first side surface SS1d. The obtuse angle between the second-second side surface SS2-2d and the second-first side surface SS2-1d of the glass substrate UGd may be an obtuse angle formed between the tangent line of the second-second side surface SS2-2d and the tangent line of the second-first side surface SS2-1d. The obtuse angle between the second-second side surface SS2-2d and the second-first side surface SS2-1d of the glass substrate UGd may be greater than about 135 degrees. As an example, the obtuse angle between the second-second side surface SS2-2d and the second-first side surface SS2-1d of the glass substrate UGd may be about 157.5 degrees.

The third side surface SS3d of the glass substrate UGd may extend from the first side surface SS1d and may be connected to the upper surface USd. The third side surface SS3d of the glass substrate UGd may include a third-first side surface SS3-1d and a third-second side surface SS3-2d.

The third-first side surface SS3-1d of the glass substrate UGd may be a surface obtained by polishing the third-first side surface SS3-1c of the third preliminary glass substrate UGc. A portion where the third-first side surface SS3-1d and the first side surface SS1d of the glass substrate UGd meet may be a curved surface. An obtuse angle between the third-first side surface SS3-1d and the first side surface SS1d of the glass substrate UGd may be about 135 degrees. In the present embodiment, the obtuse angle between the third-first side surface SS3-1d and the first side surface SS1d of the glass substrate UGd may be an obtuse angle formed between a tangent line of the third-first side surface SS3-1d and a tangent line of the first side surface SS1d.

The third-second side surface SS3-2d of the glass substrate UGd may extend from the third-first side surface SS3-1d and may be connected to the upper surface USd. The third-second side surface SS3-2d of the glass substrate UGd may be a surface obtained by polishing the third side surface SS3c of the third preliminary glass substrate UGc. An obtuse angle between the third-second side surface SS3-2d and the upper surface USd of the glass substrate UGd may be greater than the obtuse angle between the third-first side surface SS3-1d and the first side surface SS1d. The obtuse angle between the third-second side surface SS3-2d and the upper surface USd of the glass substrate UGd may be an obtuse angle formed between a tangent line of the third-second side surface SS3-2d and the upper surface USd. The obtuse angle between the third-second side surface SS3-2d and the upper surface USd of the glass substrate UGd may be greater than about 135 degrees. As an example, the obtuse angle between the third-second side surface SS3-2d and the upper surface USd of the glass substrate UGd may be about 157.5 degrees. An obtuse angle between the third-second side surface SS3-2d and the third-first side surface SS3-1d of the glass substrate UGd may be greater than the obtuse angle between the third-first side surface SS3-1d and the first side surface SS1d. The obtuse angle between the third-second side surface SS3-2d and the third-first side surface SS3-1d of the glass substrate UGd may be an obtuse angle formed between the tangent line of the third-second side surface SS3-2d and the tangent line of the third-first side surface SS3-1d. The obtuse angle between the third-second side surface SS3-2d and the third-first side surface SS3-1d of the glass substrate UGd may be greater than about 135 degrees. As an example, the obtuse angle between the third-second side surface SS3-2d and the third-first side surface SS3-1d of the glass substrate UGd may be about 157.5 degrees.

The manufacturing method of the window may further include the forming of the ink layer under the glass substrate UGd. The ink layer may be used to form the bezel pattern WM-BZ (refer to FIG. 5).

The glass substrate UGd may be the base substrate WM-BS described with reference to FIG. 5. The glass substrate UGd applied as the base substrate WM-BS included in the window WM (refer to FIG. 5) according to the present disclosure is manufactured through multiple chamfering processes, and thus, the glass substrate UGd may have a structure in which stress is not concentrated at an edge portion where the upper surface USd meets the side surface SSd or the lower surface LSd meets the side surface SSd. Accordingly, the glass substrate UGd may have excellent impact resistance against external impacts.

In some aspects, when the bezel pattern WM-BZ (refer to FIG. 5) is formed in the base substrate WM-BS (refer to FIG. 5), the thickness of the bezel pattern WM-BZ (refer to FIG. 5) may not be changed abruptly at a boundary between the lower surface LSd and the side surface SSd. Accordingly, the bezel pattern WM-BZ (refer to FIG. 5) may have excellent reliability with respect to external impacts.

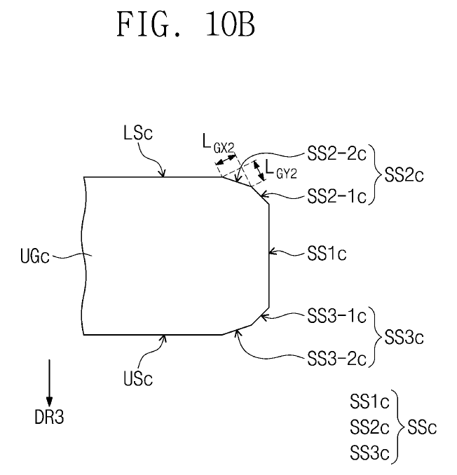

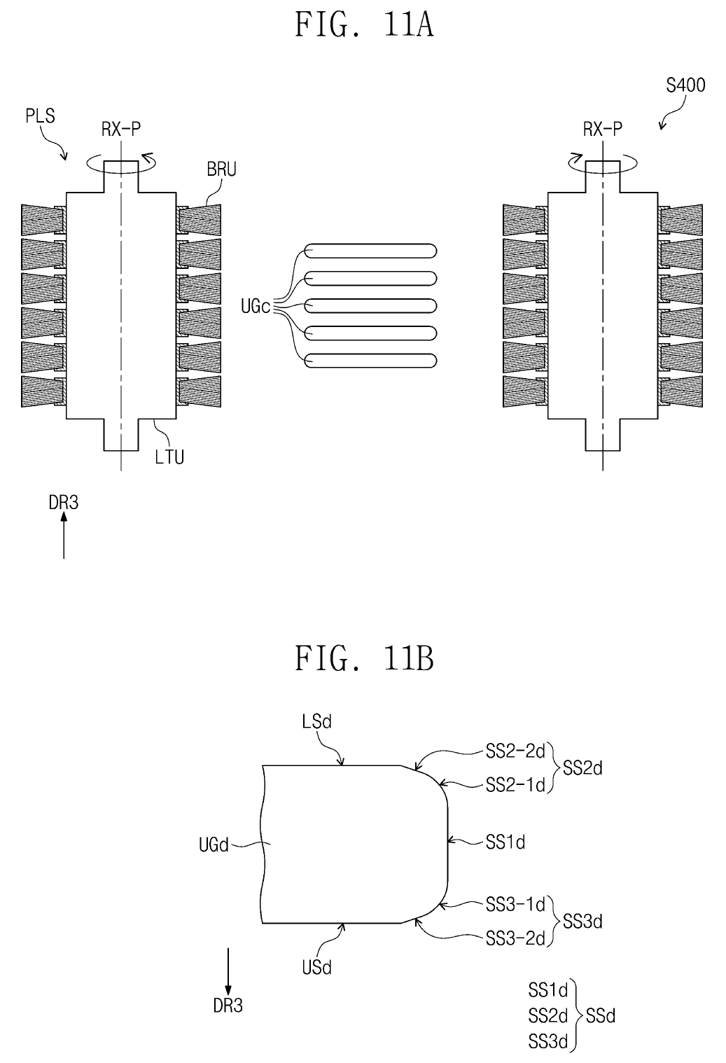

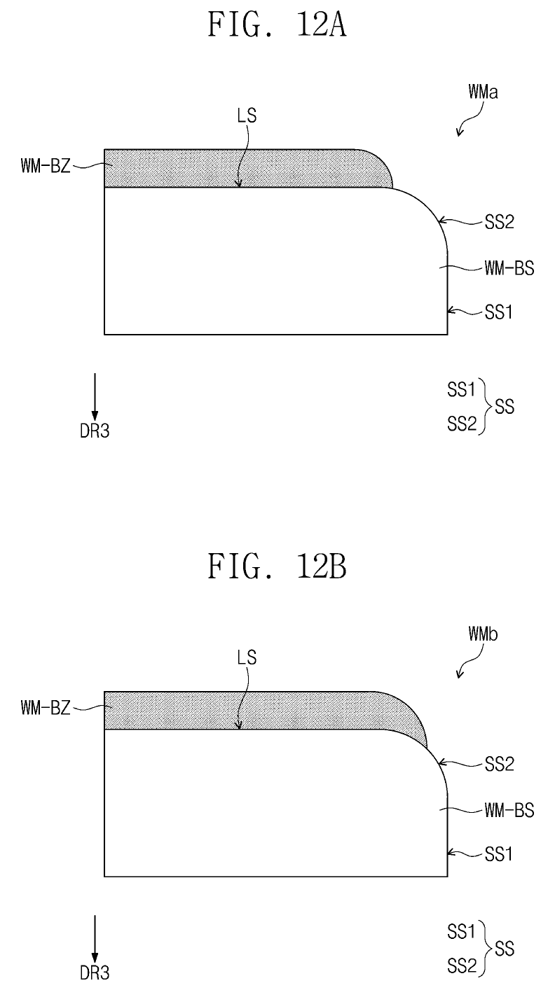

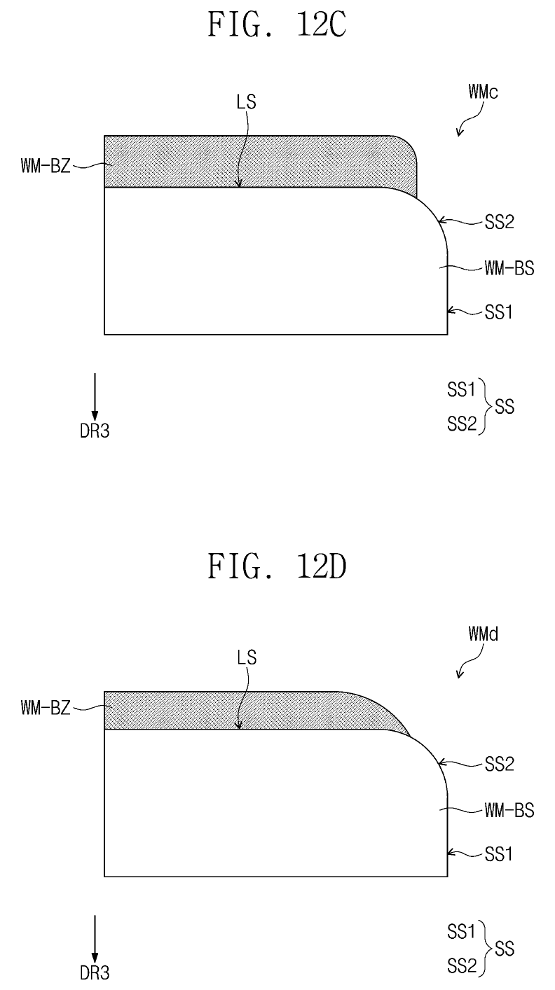

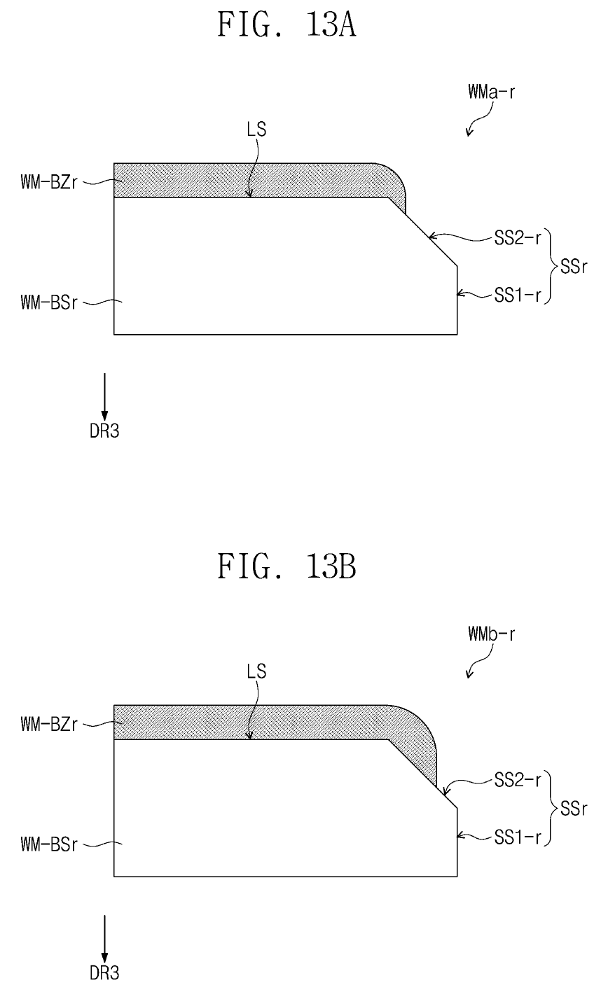

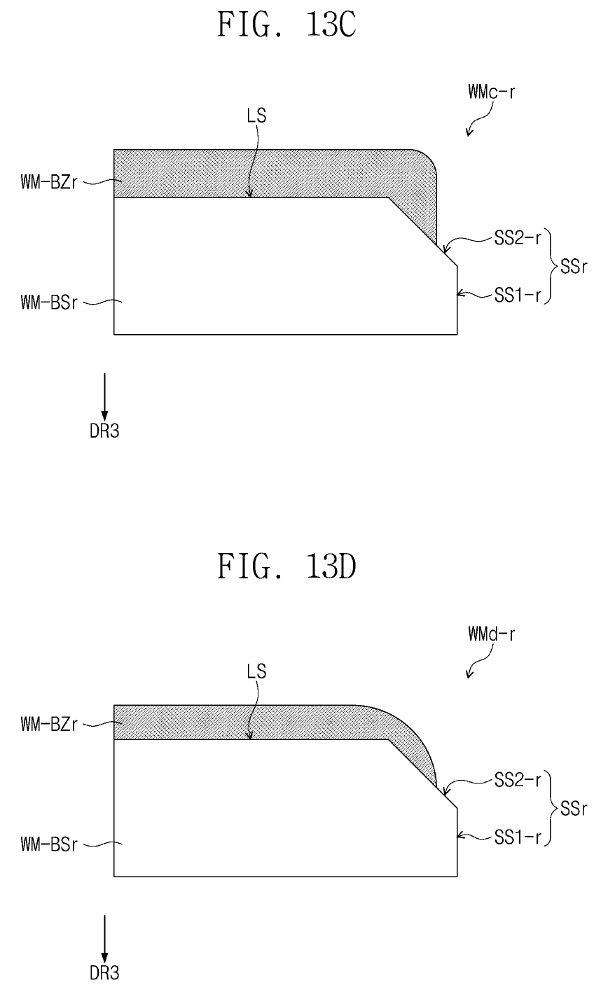

FIGS. 12A to 12D are enlarged cross-sectional views of windows according to embodiments of the present disclosure. FIGS. 13A to 13D are enlarged cross-sectional views of windows according to comparative examples.

FIGS. 12A to 12D are enlarged cross-sectional views of the windows corresponding to an area BB’ of FIG. 5 according to embodiments of the present disclosure. FIGS. 13A to 13D are enlarged cross-sectional views of the windows corresponding to the area BB’ of FIG. 5 according to comparative examples.

Referring to FIGS. 12A to 12D, each of the windows WMa, WMb, WMc, and WMd of embodiment examples 1 to 4 may include a base substrate WM-BS and a bezel pattern WM-BZ. The base substrate WM-BS of FIGS. 12A to 12D may be the glass substrate UGd of FIG. 11B. In some aspects, a lower surface LS of FIGS. 12A to 12D may be the lower surface LSd of FIG. 11B. Further, a side surface SS, a first side surface SS1, and a second side surface SS2 of FIGS. 12A to 12D may be the side surface SSd, the first side surface SS1d, and the second side surface SS2d of FIG. 11B, respectively. The base substrate WM-BS included in the windows WMa, WMb, WMc, and WMd of embodiment examples 1 to 4 may be the glass substrate manufactured through the first-chamfering process, the second-chamfering process, and the polishing process.

Since the base substrate WM-BS according to the present disclosure may have a structure where a slope does not change abruptly at a boundary between the lower surface LS and the second side surface SS2, the bezel pattern WM-BZ, which is disposed on the base substrate WM-BS, may be prevented from being detached at the boundary between the lower surface LS and the second side surface SS2, and thus, printing reliability may be improved.

Referring to FIGS. 13A to 13D, each of the windows WMa-r, WMb-r, WMc-r, and WMd-r of comparative examples 1 to 4 may include a base substrate WM-BSr and a bezel pattern WM-BZr. The base substrate WM-BSr of FIGS. 13A to 13D is a glass substrate manufactured by performing a polishing process on the first preliminary glass substrate UGb of FIG. 9B without performing additional chamfering process. Accordingly, a lower surface LS of FIGS. 13A to 13D may be the lower surface LSb of FIG. 9B. In addition, a side surface SSr, a first side surface SS1-r, and a second side surface SS2-r of FIGS. 13A to 13D may be the surface obtained by polishing the side surface SSb, the surface obtained by polishing the first side surface SS1b, and the surface obtained by polishing the second side surface SS2b of FIG. 9B, respectively.

The bezel patterns WM-BZ and WM-BZr in FIGS. 12A and 13A are formed with the same amount of ink layer as each other over the same area. FIGS. 12A and 13A illustrate cases of insufficient printing.

Referring to FIG. 12A, the bezel pattern WM-BZ of the window WMa of embodiment example 1 may have a structure in which a thickness does not change abruptly at the boundary between the lower surface LS and the second side surface SS2 of the base substrate WM-BS and the stress is not concentrated. On the other hand, referring to FIG. 13A, the bezel pattern WM-BZr of the window WMa-r of comparative example 1 has a structure in which a thickness changes abruptly at a boundary between the lower surface LS and the second side surface SS2-r of the base substrate WM-BSr and the stress is concentrated.

The bezel patterns WM-BZ and WM-BZr in FIGS. 12B and 13B are formed with the same amount of ink layer as each other over the same area. FIGS. 12B and 13B illustrate cases of printing overflow.

Referring to FIG. 12B, the bezel pattern WM-BZ of the window WMb of embodiment example 2 may have a structure in which a thickness does not change abruptly at the boundary between the lower surface LS and the second side surface SS2 of the base substrate WM-BS and the stress is not concentrated. On the other hand, referring to FIG. 13B, the bezel pattern WM-BZr of the window WMb-r of comparative example 2 has a structure in which a thickness changes abruptly at the boundary between the lower surface LS and the second side surface SS2-r of the base substrate WM-BSr and the stress is concentrated.

The bezel patterns WM-BZ and WM-BZr in FIGS. 12C and 13C are formed with the same amount of ink layer as each other over the same area. In this case, a printing height may refer to a height of the bezel patterns WM-BZ and WM-BZr disposed on the lower surface LS. FIGS. 12C and 13C illustrate cases where the printing height is formed high.

Referring to FIG. 12C, the bezel pattern WM-BZ of the window WMc of embodiment example 3 may have a structure in which a thickness does not change abruptly at the boundary between the lower surface LS and the second side surface SS2 of the base substrate WM-BS and the stress is not concentrated. On the other hand, referring to FIG. 13C, the bezel pattern WM-BZr of the window WMc-r of comparative example 3 has a structure in which a thickness changes abruptly at the boundary between the lower surface LS and the second side surface SS2-r of the base substrate WM-BSr and the stress is concentrated.

The bezel patterns WM-BZ and WM-BZr in FIGS. 12D and 13D are formed with the same amount of ink layer as each other over the same area. In this case, a printing height may refer to a height of the bezel patterns WM-BZ and WM-BZr disposed on the lower surface LS. FIGS. 12D and 13D illustrate cases where the printing height is formed high. FIGS. 12D and 13D illustrate cases of insufficient printing.

Referring to FIG. 12D, the bezel pattern WM-BZ of the window WMd of embodiment example 4 may have a structure in which a thickness does not change abruptly at the boundary between the lower surface LS and the second side surface SS2 of the base substrate WM-BS and the stress is not concentrated. On the other hand, referring to FIG. 13D, the bezel pattern WM-BZr of the window WMd-r of comparative example 4 has a structure in which a thickness changes abruptly at the boundary between the lower surface LS and the second side surface SS2-r of the base substrate WM-BSr and the stress is concentrated.

Accordingly, the base substrate WM-BS included in the windows WMa, WMb, WMc, and WMd of embodiment examples 1 to 4 illustrated in FIGS. 12A to 12D may have excellent impact resistance against external impacts, and the printing quality of the bezel pattern WM-BZ may be excellent.

Although the embodiments of the present disclosure have been described, it is understood that the present disclosure should not be limited to the example embodiments but various changes and modifications can be made by one ordinary skilled in the art within the spirit and scope of the present disclosure as hereinafter claimed.

Therefore, the disclosed subject matter should not be limited to any single embodiment described herein, and the scope of the embodiments of the present disclosure shall be determined according to the attached claims.

What is claimed is:

1. A window comprising:
a transmission area;
a bezel area surrounding the transmission area;
a base substrate comprising an upper surface, a lower surface opposite to the upper surface, and a side surface connecting the upper surface and the lower surface; and
a bezel pattern disposed under the base substrate and overlapping the bezel area,
wherein:
the side surface comprises:
a first side surface parallel to a thickness direction of the base substrate;
a second side surface extending from the first side surface and connected to the lower surface; and
a third side surface extending from the first side surface and connected to the upper surface, and
the second side surface comprises:
a second-first side surface adjacent to the first side surface; and
a second-second side surface adjacent to the lower surface,
wherein an obtuse angle between the lower surface and the second-second side surface is greater than about 135 degrees.

2. The window of claim 1, wherein an obtuse angle between the second-first side surface and the second-second side surface is greater than about 135 degrees.

3. The window of claim 1, wherein:
a boundary at which the first side surface meets the second-first side surface comprises a curved surface, and
a boundary at which the second-first side surface meets the second-second side surface comprises a curved surface.

4. The window of claim 1, wherein the obtuse angle between the lower surface and the second-second side surface is greater than an obtuse angle between the first side surface and the second-first side surface.

5. The window of claim 1, wherein an obtuse angle between the second-first side surface and the second-second side surface is greater than an obtuse angle between the first side surface and the second-first side surface.

6. The window of claim 1, wherein the base substrate has a thickness smaller than or equal to about 1mm.

7. The window of claim 1, wherein the third side surface comprises:
a third-first side surface adjacent to the first side surface; and
a third-second side surface adjacent to the upper surface.

8. The window of claim 7, wherein:
an obtuse angle between the upper surface and the third-second side surface is greater than about 135 degrees, and
an obtuse angle between the third-first side surface and the third-second side surface is greater than about 135 degrees.

9. The window of claim 7, wherein:
a boundary at which the first side surface meets the third-first side surface comprises a curved surface,
and a boundary at which the third-first side surface meets the third-second side surface comprises a curved surface.

10. The window of claim 1, wherein the bezel pattern is disposed directly on a portion of the lower surface and a portion of the side surface.

11. A method of manufacturing a window, comprising:
providing a first preliminary glass substrate comprising an upper surface, a lower surface opposite to the upper surface, and a first side surface connecting the upper surface and the lower surface and perpendicular to the upper surface and the lower surface;
forming a second preliminary glass substrate by first-chamfering the first preliminary glass substrate, the second preliminary glass substrate comprising a second preliminary side surface connecting the lower surface and the first side surface; and
forming a third preliminary glass substrate by second-chamfering the second preliminary glass substrate, the third preliminary glass substrate comprising a second-first side surface adjacent to the first side surface and a second-second side surface connecting the second-first side surface and the lower surface.

12. The method of claim 11, wherein the forming of the third preliminary glass substrate is performed by chamfering an edge defined by the lower surface and the second preliminary side surface of the second preliminary glass substrate, wherein based on the chamfering of the edge, each of an obtuse angle between the lower surface and the second-second side surface of the third preliminary glass substrate and an obtuse angle between the second-second side surface and the second-first side surface of the third preliminary glass substrate is greater than an obtuse angle between the first side surface and the second-first side surface.

13. The method of claim 11, further comprising forming a base substrate, wherein the forming of the base substrate comprises polishing the third preliminary glass substrate such that:
a boundary at which the first side surface meets the second-first side surface comprises a curved surface; and
a boundary at which the second-first side surface meets the second-second side surface of the base substrate comprises a curved surface.

14. The method of claim 13, further comprising forming a bezel pattern in a portion of a lower surface of the base substrate.

15. The method of claim 11, wherein the forming of the third preliminary glass substrate is performed such that an obtuse angle between the lower surface and the second-second side surface of the third preliminary glass substrate is greater than about 135 degrees.

16. An electronic device comprising:
a display panel comprising a display area and a non-display area surrounding the display area; and
a window disposed on the display panel and comprising:
a transmission area overlapping the display area;
a bezel area overlapping the non-display area;
a base substrate comprising an upper surface, a lower surface opposite to the upper surface, and a side surface connecting the upper surface and the lower surface; and
a bezel pattern disposed under the base substrate and overlapping the bezel area,
wherein:
the side surface comprises:
a first side surface parallel to a thickness direction of the base substrate;
a second side surface extending from the first side surface and connected to the lower surface; and
a third side surface extending from the first side surface and connected to the upper surface, and
the second side surface comprises:
a second-first side surface adjacent to the first side surface and a second-second side surface adjacent to the lower surface,
wherein an obtuse angle between the lower surface and the second-second side surface is greater than about 135 degrees.

17. The electronic device of claim 16, wherein:
a boundary at which the first side surface meets the second-first side surface comprises a curved surface, and
a boundary at which the second-first side surface meets the second-second side surface comprises a curved surface.

18. The electronic device of claim 16, wherein the obtuse angle between the lower surface and the second-second side surface is greater than an obtuse angle between the first side surface and the second-first side surface.

19. The electronic device of claim 16, further comprising at least one of a processor, a memory, or a power module.

20. The electronic device of claim 16, wherein the electronic device is a television, a monitor, an outdoor billboard, a personal computer, a notebook computer, a personal digital assistant, a car dashboard, a center fascia, a navigation unit, a room mirror display, a game unit, a smartphone, a tablet computer, a smart watch, a smart glasses, a head-mounted display, or a camera.
